(19) United States
(12) Patent Application Publication
(10) Pub. No.: US 2024/0161393 A1
(43) Pub. Date: May 16, 2024

(54) REMOTE OPERATING A BUILDING INFORMATION MODELING SYSTEM USING CAPTURED POINT CLOUDS

(71) Applicant: FARO Technologies, Inc., Lake Mary, FL (US)

(72) Inventors: Marc ZSCHIESCHANG, Pirna (DE); Jana SIEBENBRODT, Dresden (DE); Joachim BANK, Saxony (DE); Tilo PFLIEGNER, Dresden (DE); Sören KÖNIG, Dresden (DE)

(21) Appl. No.: 18/364,836

(22) Filed: Aug. 3, 2023

Related U.S. Application Data
(60) Provisional application No. 63/424,569, filed on Nov. 11, 2022.

(51) Int. Cl. G06T 17/00; G06F 3/04815; G06F 3/04842; G06F 9/54

(52) U.S. Cl. CPC G06T 17/00; G06F 3/04815; G06F 3/04842; G06F 9/548; G06F 3/023; G06T 2200/24; G06T 2210/56

(57) ABSTRACT

A computer-implemented method includes establishing a connection between a point cloud browser and a transfer agent. The method further includes establishing a connection between the transfer agent and a target application. The method further includes in response to selection of one or more points in the point cloud browser, generating one or more objects in the target application.

### CROSS-REFERENCE TO RELATED APPLICATIONS

This application claims the benefit of U.S. Provisional Patent Application Ser. No. 63/424,569, filed Nov. 11, 2022, and entitled “REMOTE OPERATING A BUILDING INFORMATION MODELING SYSTEM USING CAPTURED POINT CLOUDS,” the contents of which are incorporated by reference herein in their entirety.

### BACKGROUND

The subject matter disclosed herein relates to use of a three-dimensional (“3D”) measurement device, such as a laser scanner time-of-flight (TOF) coordinate measurement device and particularly, use of the 3D measurement device when developing digital representations of places using building information modeling (BIM) systems.

BIM systems are used to generate and/or manipulate digital files that contain information about one or more built assets and facilitate to plan, design, construct, operate and maintain buildings and diverse physical infrastructures. For example, BIM systems are used throughout the life cycle of such physical infrastructure and, thus, play a prominent role in management of assets such as communication utilities, roads, railways, bridges, ports, tunnels, factories, warehouses, office buildings, houses, or any other such construction related projects.

A 3D measurement device can be, for example, a 3D laser scanner of this type steers a beam of light to a non-cooperative target such as a diffusely scattering surface of an object. A distance meter in the device measures a distance to the object, and angular encoders measure the angles of rotation of two axles in the device. The measured distance and two angles enable a processor in the device to determine the 3D coordinates of the target.

A time-of-flight (TOF) laser scanner is a scanner in which the distance to a target point is determined based on the speed of light in air between the scanner and a target point. Laser scanners are typically used for scanning closed or open spaces such as interior areas of buildings, industrial installations, and tunnels. They may be used, for example, in industrial applications and accident reconstruction applications. A laser scanner optically scans and measures objects in a volume around the scanner through the acquisition of data points representing object surfaces within the volume. Such data points are obtained by transmitting a beam of light onto the objects and collecting the reflected or scattered light to determine the distance, two-angles (i.e., an azimuth and a zenith angle), and optionally a gray-scale value. This raw scan data is collected, stored, and sent to a processor or processors to generate a 3D image representing the scanned area or object.

Generating an image requires at least three values for each data point. These three values may include the distance and two angles, or may be transformed values, such as the x, y, z coordinates.

Most TOF scanners direct the beam of light within the measurement volume by steering the light with a beam steering mechanism. The beam steering mechanism includes a first motor that steers the beam of light about a first axis by a first angle that is measured by a first angular encoder (or other angle transducer). The beam steering mechanism also includes a second motor that steers the beam of light about a second axis by a second angle that is measured by a second angular encoder (or other angle transducer). As a result of the scan, a collection of 3D coordinates is generated for points on surfaces in the environment. This collection of 3D coordinates is sometimes referred to as a “point cloud.” In many applications, multiple scans may be performed in an environment to acquire the desired measurements.

Many contemporary laser scanners include a camera mounted on the laser scanner for gathering camera digital images of the environment and for presenting the camera digital images to an operator of the laser scanner. By viewing the camera images, the operator of the scanner can determine the field of view of the measured volume and adjust settings on the laser scanner to measure over a larger or smaller region of space. In addition, the camera digital images may be transmitted to a processor to add color to the scanner image. To generate a color scanner image, at least three positional coordinates (such as x, y, z) and three color values (such as red, green, blue “RGB”) are collected for each data point.

When generating the point cloud, artifacts (i.e., aberrations) can be unintendedly captured by the TOF scanner. This may occur for example, when one or more scans are performed with an area of overlap. Removing artifacts from the point cloud is usually performed in a manual operation. Having individuals correct the resulting point cloud is therefore tedious and time consuming.

Accordingly, while existing BIM systems, 3D scanners and image processing techniques are suitable for their intended purposes, what is needed is further integration and interplay of such systems having certain features of embodiments of the present invention.

### BRIEF SUMMARY OF THE INVENTION

According to an embodiment, a computer-implemented method includes establishing a connection between a point cloud browser and a transfer agent. The method further includes establishing a connection between the transfer agent and a target application. The method further includes in response to selection of one or more points in the point cloud browser, generating one or more objects in the target application.

In one or more aspects, the one or more objects comprise at least one of a graphical element, a textual element, and a computer-executable instruction.

In one or more aspects, the point cloud browser displays a point cloud stored on a remote computer server, and in response to the selection of the one or more points, an extracted data is generated corresponding to the selection.

In one or more aspects, only the extracted data is sent for receipt by the transfer agent.

In one or more aspects, the transfer agent generates the one or more objects in the target application by generating one or more commands that use the extracted data, the commands based on an application programming interface of the target application.

In one or more aspects, the transfer agent generates the one or more objects in the target application by emulating a keyboard input that is provided to the target application.

According to an embodiment, a system includes a memory comprising computer readable instructions and a processing device for executing the computer readable instructions. The computer readable instructions control the processing device to perform operations. The operations include establishing a connection between a point cloud browser and a transfer agent. The operations further include establishing a connection between the transfer agent and a target application. The operations further include, in response to selection of one or more points in the point cloud browser, generating one or more objects in the target application.

In one or more aspects, the one or more objects comprise at least one of a graphical element, a textual element, and a computer-executable instruction.

In one or more aspects, the point cloud browser displays a point cloud stored on a remote computer server, and in response to the selection of the one or more points, an extracted data is generated corresponding to the selection.

In one or more aspects, only the extracted data is sent for receipt by the transfer agent.

In one or more aspects, the transfer agent generates the one or more objects in the target application by generating one or more commands that use the extracted data, the commands based on an application programming interface of the target application.

In one or more aspects, the transfer agent generates the one or more objects in the target application by emulating a keyboard input that is provided to the target application.

According to an embodiment, a computer program product includes a computer readable storage medium having program instructions embodied therewith, the program instructions executable by one or more processors to cause the one or more processors to perform operations. The operations include establishing a connection between a point cloud browser and a transfer agent. The operations further include establishing a connection between the transfer agent and a target application. The operations further include in response to selection of one or more points in the point cloud browser, generating one or more objects in the target application.

In one or more aspects, the one or more objects comprise at least one of a graphical element, a textual element, and a computer-executable instruction.

In one or more aspects, the point cloud browser displays a point cloud stored on a remote computer server, and in response to the selection of the one or more points, an extracted data is generated corresponding to the selection.

In one or more aspects, only the extracted data is sent for receipt by the transfer agent.

In one or more aspects, the transfer agent generates the one or more objects in the target application by generating one or more commands that use the extracted data, the commands based on an application programming interface of the target application.

In one or more aspects, the transfer agent generates the one or more objects in the target application by emulating a keyboard input that is provided to the target application.

These and other advantages and features will become more apparent from the following description taken in conjunction with the drawings.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The subject matter, which is regarded as the invention, is particularly pointed out and distinctly claimed in the claims at the conclusion of the specification. The foregoing and other features, and advantages of embodiments of the invention are apparent from the following detailed description taken in conjunction with the accompanying drawings.

FIGS. 1-3 are schematic illustrations of a coordinate measurement device according to one or more embodiments described herein;

FIG. 4 is a block diagram of a coordinate measurement device according to one or more embodiments described herein;

FIG. 5 is a block diagram of a computer system for implementing one or more embodiments described herein;

FIG. 6 is a block diagram of a computer system for operating a BIM system from a web app using captured point clouds according to one or more embodiments;

FIG. 7 depicts an operational flow of a method to remotely control a BIM using a web application according to one or more embodiments described herein;

FIG. 8 depicts an example with the point cloud browser and the BIM shown in a side-by-side view according to one or more embodiments described herein;

FIG. 9 depicts an example with an operating selecting a wall in a point cloud according to one or more embodiments described herein;

FIG. 10 depicts the operational workflow of operating the BIM remotely via the point cloud browser according to one or more embodiments described herein;

FIGS. 11A and 11B depict examples of communication between the point cloud browser and the target application according to one or more embodiments described herein;

FIG. 12 depicts another example of remotely operating a target application via selection of one or more points in the point cloud in the point cloud browser according to one or more embodiments described herein; and

FIG. 13 depicts another example of remotely operating a target application via selection of one or more points in the point cloud in the point cloud browser according to one or more embodiments described herein.

The detailed description explains embodiments of the invention, together with advantages and features, by way of example with reference to the drawings.

### DETAILED DESCRIPTION

One or more aspects of the technical solutions described herein relate to using a first system, such as a web-based application to extract data from a reality capture data (laser scans, point clouds, panorama images, meshes, etc.) and send the extracted data to a second system, such as a building information modeling (BIM) system. In some aspects, the reality capture data is hosted on a third system, such as a computer server (e.g., cloud platform). The first system, in some aspects, is associated with a coordinate measurement device, such as a laser scanner. In other aspects, the first system is a computer program that can access the reality capture data recorded using the coordinate measurement device, extract the desired data, and transform the extracted data into a format associated with the second system. In yet other aspects, a separate transformation module may be used that transforms the extracted data provided by the first system into the format associated with the second system. In some aspects, the first system and the second system are computer programs that are being executed on the same computing device (e.g., desktop computer, tablet computer, phone, etc.), which is in communication with the computer server that hosts the reality capture data.

Aspects of the technical solutions herein facilitate interactive modelling in the target BIM system by using the first system, for example, a web-based application (“web app”) like a remote control, without the need to download, convert, and import the reality capture data into the target BIM application. This addresses a technical challenge with using the reality capture data in the BIM application, because the size of the data is generally prohibitive of real-time operations and/or use of the data. Typically, downloading, converting, and importing the reality capture data can take several minutes, if not hours, because the size of the data ranges in several gigabytes (GB). Hence, even with a fast processor, and communication network, which are the significant bottlenecks, real-time operations for interactivity between the first and second systems

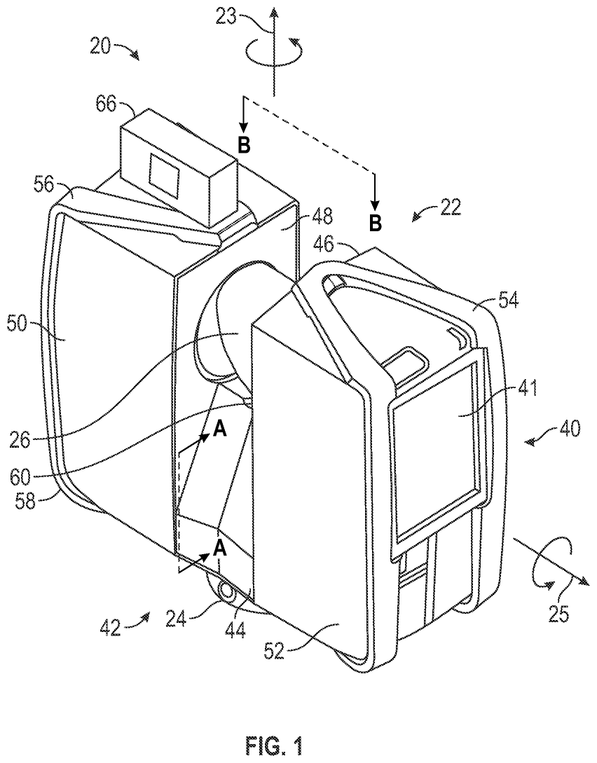

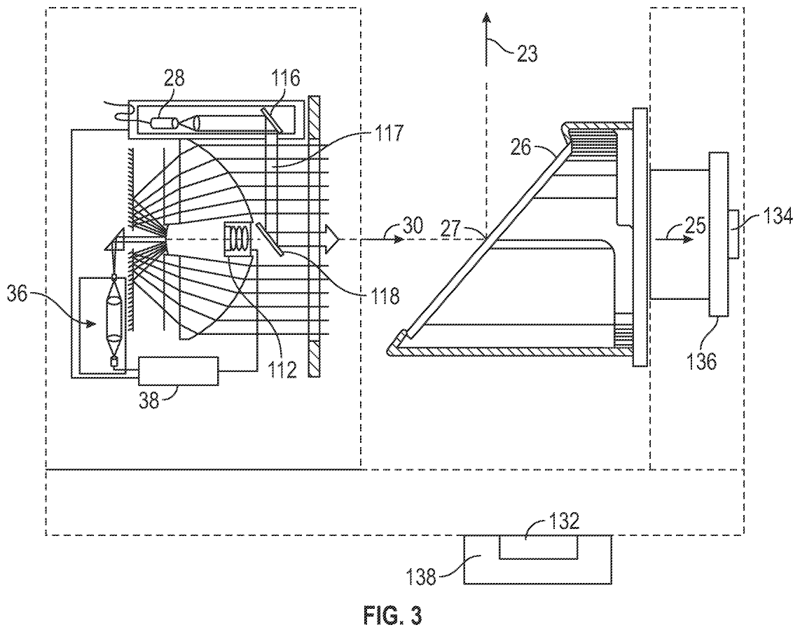

Referring now to FIGS. 1-3, a coordinate measurement device, such as a laser scanner 20, is depicted for optically scanning and measuring the environment surrounding the laser scanner 20. The laser scanner 20 has a measuring head 22 and a base 24. The measuring head 22 is mounted on the base 24 such that the laser scanner 20 may be rotated about a vertical axis 23. In one embodiment, the measuring head 22 includes a gimbal point 27 that is a center of rotation about the vertical axis 23 and a horizontal axis 25. The measuring head 22 has a rotary mirror 26, which may be rotated about the horizontal axis 25. The rotation about the vertical axis may be about the center of the base 24. The terms vertical axis and horizontal axis refer to the scanner in its normal upright position. It is possible to operate a 3D coordinate measurement device on its side or upside down, and so to avoid confusion, the terms azimuth axis and zenith axis may be substituted for the terms vertical axis and horizontal axis, respectively. The term pan axis or standing axis may also be used as an alternative to vertical axis.

The measuring head 22 is further provided with an electromagnetic radiation emitter, such as light emitter 28, for example, which emits an emitted light beam 30. In one embodiment, the emitted light beam 30 is a coherent light beam such as a laser beam. The laser beam may have a wavelength range of approximately 300 to 1600 nanometers, for example 790 nanometers, 905 nanometers, 1550 nm, or less than 400 nanometers. It should be appreciated that other electromagnetic radiation beams having greater or smaller wavelengths may also be used. The emitted light beam 30 is amplitude or intensity modulated, for example, with a sinusoidal waveform or with a rectangular waveform. The emitted light beam 30 is emitted by the light emitter 28 onto a beam steering unit, such as mirror 26, where it is deflected to the environment. A reflected light beam 32 is reflected from the environment by an object 34. The reflected or scattered light is intercepted by the rotary mirror 26 and directed into a light receiver 36. The directions of the emitted light beam 30 and the reflected light beam 32 result from the angular positions of the rotary mirror 26 and the measuring head 22 about the axes 25 and 23, respectively. These angular positions in turn depend on the corresponding rotary drives or motors.

Coupled to the light emitter 28 and the light receiver 36 is a controller 38. The controller 38 determines, for a multitude of measuring points X, a corresponding number of distances d between the laser scanner 20 and the points X on object 34. The distance to a particular point X is determined based at least in part on the speed of light in air through which electromagnetic radiation propagates from the device to the object point X. In one embodiment the phase shift of modulation in light emitted by the laser scanner 20 and the point X is determined and evaluated to obtain a measured distance d.

The speed of light in air depends on the properties of the air such as the air temperature, barometric pressure, relative humidity, and concentration of carbon dioxide. Such air properties influence the index of refraction n of the air. The speed of light in air is equal to the speed of light in vacuum c divided by the index of refraction. In other words, cₐᵢᵣ=c/n. A laser scanner of the type discussed herein is based on the time-of-flight (TOF) of the light in the air (the round-trip time for the light to travel from the device to the object and back to the device). Examples of TOF scanners include scanners that measure round trip time using the time interval between emitted and returning pulses (pulsed TOF scanners), scanners that modulate light sinusoidally and measure phase shift of the returning light (phase-based scanners), as well as many other types. A method of measuring distance based on the time-of-flight of light depends on the speed of light in air and is therefore easily distinguished from methods of measuring distance based on triangulation. Triangulation-based methods involve projecting light from a light source along a particular direction and then intercepting the light on a camera pixel along a particular direction. By knowing the distance between the camera and the projector and by matching a projected angle with a received angle, the method of triangulation enables the distance to the object to be determined based on one known length and two known angles of a triangle. The method of triangulation, therefore, does not directly depend on the speed of light in air.

In one mode of operation, the scanning of the volume around the laser scanner 20 takes place by rotating the rotary mirror 26 relatively quickly about axis 25 while rotating the measuring head 22 relatively slowly about axis 23, thereby moving the assembly in a spiral pattern. In an exemplary embodiment, the rotary mirror rotates at a maximum speed of 5820 revolutions per minute. For such a scan, the gimbal point 27 defines the origin of the local stationary reference system. The base 24 rests in this local stationary reference system.

In addition to measuring a distance d from the gimbal point 27 to an object point X, the scanner 20 may also collect gray-scale information related to the received optical power (equivalent to the term “brightness”). The gray-scale value may be determined at least in part, for example, by integration of the bandpass-filtered and amplified signal in the light receiver 36 over a measuring period attributed to the object point X.

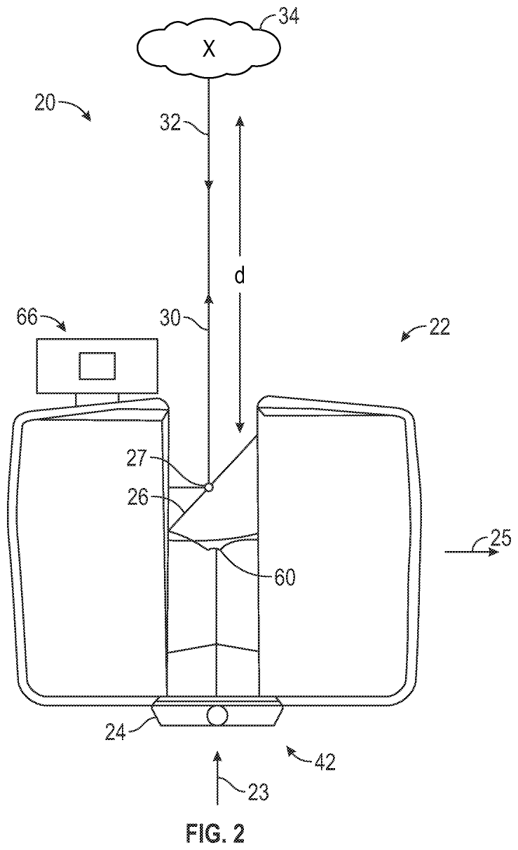

The measuring head 22 may include a display device 40 integrated into the laser scanner 20. The display device 40 may include a graphical touch screen 41, as shown in FIG. 2, which allows the operator to set the parameters or initiate the operation of the laser scanner 20. For example, the screen 41 may have a user interface that allows the operator to provide measurement instructions to the device, and the screen may also display measurement results.

The laser scanner 20 includes a carrying structure 42 that provides a frame for the measuring head 22 and a platform for attaching the components of the laser scanner 20. In one embodiment, the carrying structure 42 is made from a metal such as aluminum. The carrying structure 42 includes a traverse member 44 having a pair of walls 46, 48 on opposing ends. The walls 46, 48 are parallel to each other and extend in a direction opposite the base 24. Shells 50, 52 are coupled to the walls 46, 48 and cover the components of the laser scanner 20. In the exemplary embodiment, the shells 50, 52 are made from a plastic material, such as polycarbonate or polyethylene for example. The shells 50, 52 cooperate with the walls 46, 48 to form a housing for the laser scanner 20.

On an end of the shells 50, 52 opposite the walls 46, 48 a pair of yokes 54, 56 are arranged to partially cover the respective shells 50, 52. In the exemplary embodiment, the yokes 54, 56 are made from a suitably durable material, such as aluminum for example, which assists in protecting the shells 50, 52 during transport and operation. The yokes 54, 56 each includes a first arm portion 58 that is coupled, such as with a fastener for example, to the traverse 44 adjacent the base 24. The arm portion 58 for each yoke 54, 56 extends from the traverse 44 obliquely to an outer corner of the respective shell 50, 52. From the outer corner of the shell, the yokes 54, 56 extend along the side edge of the shell to an opposite outer corner of the shell. Each yoke 54, 56 further includes a second arm portion that extends obliquely to the walls 46, 48. It should be appreciated that the yokes 54, 56 may be coupled to the traverse 42, the walls 46, 48 and the shells 50, 54 at multiple locations.

The pair of yokes 54, 56 cooperate to circumscribe a convex space within which the two shells 50, 52 are arranged. In the exemplary embodiment, the yokes 54, 56 cooperate to cover all of the outer edges of the shells 50, 54, while the top and bottom arm portions project over at least a portion of the top and bottom edges of the shells 50, 52. This provides advantages in protecting the shells 50, 52 and the measuring head 22 from damage during transportation and operation. In other embodiments, the yokes 54, 56 may include additional features, such as handles to facilitate the carrying of the laser scanner 20 or attachment points for accessories for example.

On top of the traverse 44, a prism 60 is provided. The prism extends parallel to the walls 46, 48. In the exemplary embodiment, the prism 60 is integrally formed as part of the carrying structure 42. In other embodiments, the prism 60 is a separate component that is coupled to the traverse 44. When the mirror 26 rotates, during each rotation the mirror 26 directs the emitted light beam 30 onto the traverse 44 and the prism 60. Due to non-linearities in the electronic components, for example in the light receiver 36, the measured distances d may depend on signal strength, which may be measured in optical power entering the scanner or optical power entering optical detectors within the light receiver 36, for example. In an embodiment, a distance correction is stored in the scanner as a function (possibly a nonlinear function) of distance to a measured point and optical power (generally unsealed quantity of light power sometimes referred to as “brightness”) returned from the measured point and sent to an optical detector in the light receiver 36. Since the prism 60 is at a known distance from the gimbal point 27, the measured optical power level of light reflected by the prism 60 may be used to correct distance measurements for other measured points, thereby allowing for compensation to correct for the effects of environmental variables such as temperature. In the exemplary embodiment, the resulting correction of distance is performed by the controller 38.

In an embodiment, the base 24 is coupled to a swivel assembly (not shown) such as that described in commonly owned U.S. Pat. No. 8,705,012 ('012), which is incorporated by reference herein. The swivel assembly is housed within the carrying structure 42 and includes a motor 138 that is configured to rotate the measuring head 22 about the axis 23. In an embodiment, the angular/rotational position of the measuring head 22 about the axis 23 is measured by angular encoder 134.

An auxiliary image acquisition device 66 may be a device that captures and measures a parameter associated with the scanned area or the scanned object and provides a signal representing the measured quantities over an image acquisition area. The auxiliary image acquisition device 66 may be, but is not limited to, a pyrometer, a thermal imager, an ionizing radiation detector, or a millimeter-wave detector. In an embodiment, the auxiliary image acquisition device 66 is a color camera.

In an embodiment, a central color camera (first image acquisition device) 112 is located internally to the scanner and may have the same optical axis as the 3D scanner device. In this embodiment, the first image acquisition device 112 is integrated into the measuring head 22 and arranged to acquire images along the same optical pathway as emitted light beam 30 and reflected light beam 32. In this embodiment, the light from the light emitter 28 reflects off a fixed mirror 116 and travels to dichroic beam-splitter 118 that reflects the light 117 from the light emitter 28 onto the rotary mirror 26. In an embodiment, the mirror 26 is rotated by a motor 136 and the angular/rotational position of the mirror is measured by angular encoder 134. The dichroic beam-splitter 118 allows light to pass through at wavelengths different than the wavelength of light 117. For example, the light emitter 28 may be a near infrared laser light (for example, light at wavelengths of 780 nm or 1150 nm), with the dichroic beam-splitter 118 configured to reflect the infrared laser light while allowing visible light (e.g., wavelengths of 400 to 700 nm) to transmit through. In other embodiments, the determination of whether the light passes through the beam-splitter 118 or is reflected depends on the polarization of the light. The digital camera 112 obtains 2D images of the scanned area to capture color data to add to the scanned image. In the case of a built-in color camera having an optical axis coincident with that of the 3D scanning device, the direction of the camera view may be easily obtained by simply adjusting the steering mechanisms of the scanner—for example, by adjusting the azimuth angle about the axis 23 and by steering the mirror 26 about the axis 25.

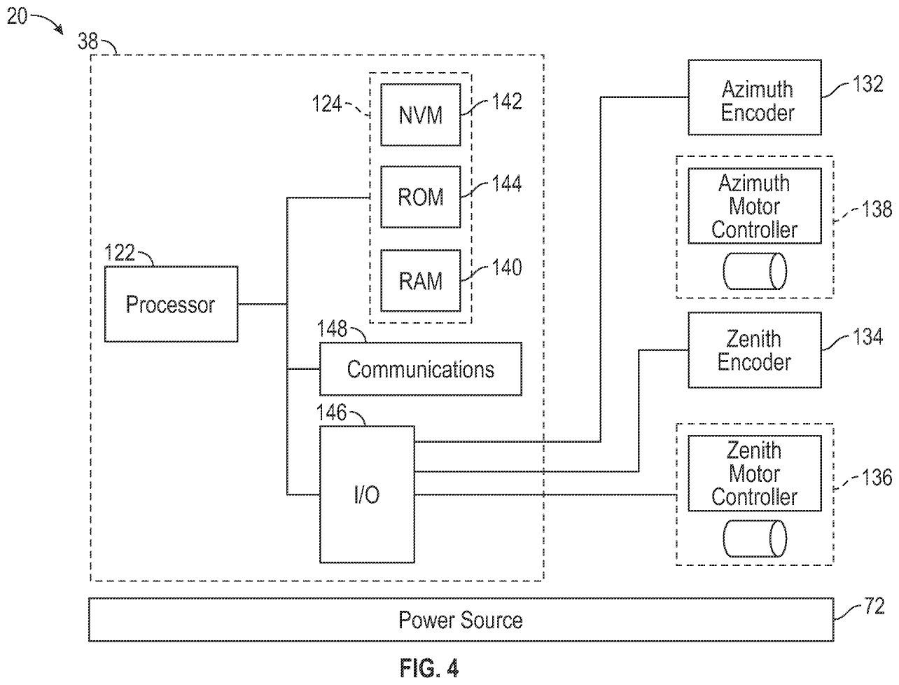

Referring now to FIG. 4 with continuing reference to FIGS. 1-3, elements are shown of the laser scanner 20. Controller 38 is a suitable electronic device capable of accepting data and instructions, executing the instructions to process the data, and presenting the results. The controller 38 includes one or more processing elements 122. The processors may be microprocessors, field programmable gate arrays (FPGAs), digital signal processors (DSPs), and generally any device capable of performing computing functions. The one or more processors 122 have access to memory 124 for storing information.

Controller 38 is capable of converting the analog voltage or current level provided by light receiver 36 into a digital signal to determine a distance from the laser scanner 20 to an object in the environment. Controller 38 uses the digital signals that act as input to various processes for controlling the laser scanner 20. The digital signals represent one or more laser scanner 20 data including but not limited to distance to an object, images of the environment, images acquired by panoramic camera 126, angular/rotational measurements by a first or azimuth encoder 132, and angular/rotational measurements by a second axis or zenith encoder 134.

In general, controller 38 accepts data from encoders 132, 134, light receiver 36, light source 28, and panoramic camera 126 and is given certain instructions for the purpose of generating a 3D point cloud of a scanned environment. Controller 38 provides operating signals to the light source 28, light receiver 36, panoramic camera 126, zenith motor 136 and azimuth motor 138. The controller 38 compares the operational parameters to predetermined variances and if the predetermined variance is exceeded, generates a signal that alerts an operator to a condition. The data received by the controller 38 may be displayed on a user interface 40 coupled to controller 38. The user interface 40 may be one or more LEDs (light-emitting diodes), an LCD (liquid-crystal diode) display, a CRT (cathode ray tube) display, a touchscreen display or the like. A keypad may also be coupled to the user interface for providing data input to controller 38. In one embodiment, the user interface is arranged or executed on a mobile computing device that is coupled for communication, such as via a wired or wireless communications medium (e.g., Ethernet, serial, USB, Bluetooth™ or WiFi) for example, to the laser scanner 20.

The controller 38 may also be coupled to external computer networks such as a local area network (LAN) and the Internet. A LAN interconnects one or more remote computers, which are configured to communicate with controller 38 using a well-known computer communications protocol such as TCP/IP (Transmission Control Protocol/Internet(\hat{ }) Protocol), RS-232, ModBus, and the like. Additional systems may also be connected to LAN with the controllers 38 in each of these systems being configured to send and receive data to and from remote computers and other systems. The LAN may be connected to the Internet. This connection allows controller 38 to communicate with one or more remote computers connected to the Internet.

The processors 122 are coupled to memory 124. The memory 124 may include random access memory (RAM) device 140, a non-volatile memory (NVM) device 142, and a read-only memory (ROM) device 144. In addition, the processors 122 may be connected to one or more input/output (I/O) controllers 146 and a communications circuit 148. In an embodiment, the communications circuit 148 provides an interface that allows wireless or wired communication with one or more external devices or networks, such as the LAN discussed above.

Controller 38 includes operation control methods embodied in application code. These methods are embodied in computer instructions written to be executed by processors 122, typically in the form of software. The software can be encoded in any language, including, but not limited to, assembly language, VHDL (Verilog Hardware Description Language), VHSIC HDL (Very High Speed IC Hardware Description Language), Fortran (formula translation), C, C++, C#, Objective-C, Visual C++, Java, ALGOL (algorithmic language), BASIC (beginners all-purpose symbolic instruction code), visual BASIC, ActiveX, HTML (HyperText Markup Language), Python, Ruby and any combination or derivative of at least one of the foregoing.

It should be appreciated that while some embodiments herein describe a point cloud that is generated by a TOF scanner, this is for example purposes and the claims should not be so limited. In other embodiments, the point cloud may be generated or created using other types of scanners, such as but not limited to triangulation scanners, area scanners, structured-light scanners, laser line scanners, flying dot scanners, and photogrammetry devices for example.

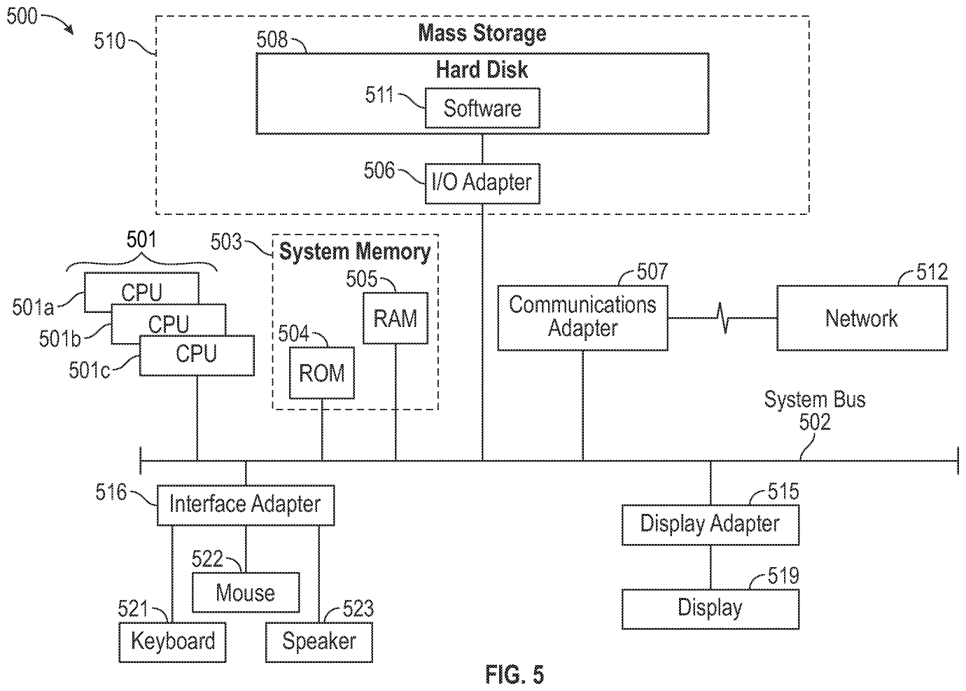

Turning now to FIG. 5, a computer system 500 is generally shown according to one or more embodiments described herein. The computer system 500 can be an electronic, computer framework comprising and/or employing any number and combination of computing devices and networks utilizing various communication technologies, as described herein. The computer system 500 can be easily scalable, extensible, and modular, with the ability to change to different services or reconfigure some features independently of others. The computer system 500 can be, for example, a server, desktop computer, laptop computer, tablet computer, or smartphone. In some examples, computer system 500 can be a cloud computing node. Computer system 500 can be described in the general context of computer system executable instructions, such as program modules, being executed by a computer system. Generally, program modules can include routines, programs, objects, components, logic, data structures, and so on that perform particular tasks or implement particular abstract data types. Computer system 500 can be practiced in distributed cloud computing environments where tasks are performed by remote processing devices that are linked through a communications network. In a distributed cloud computing environment, program modules can be located in both local and remote computer system storage media including memory storage devices.

As shown in FIG. 5, the computer system 500 has one or more central processing units (CPU(s)) 501a, 501b, 501c, etc., (collectively or generically referred to as processor(s) 501). The processors 501 can be a single-core processor, multi-core processor, computing cluster, or any number of other configurations. The processors 501, also referred to as processing circuits, are coupled via a system bus 502 to a system memory 503 and various other components. The system memory 503 can include a read only memory (ROM) 504 and a random access memory (RAM) 505. The ROM 504 is coupled to the system bus 502 and can include a basic input/output system (BIOS) or its successors like Unified Extensible Firmware Interface (UEFI), which controls certain basic functions of the computer system 500. The RAM is read-write memory coupled to the system bus 502 for use by the processors 501. The system memory 503 provides temporary memory space for operations of said instructions during operation. The system memory 503 can include random access memory (RAM), read only memory, flash memory, or any other suitable memory systems.

The computer system 500 comprises an input/output (I/O) adapter 506 and a communications adapter 507 coupled to the system bus 502. The I/O adapter 506 can be a small computer system interface (SCSI) adapter that communicates with a hard disk 508 and/or any other similar component. The I/O adapter 506 and the hard disk 508 are collectively referred to herein as a mass storage 510.

Software 511 for execution on the computer system 500 can be stored in the mass storage 510. The mass storage 510 is an example of a tangible storage medium readable by the processors 501, where the software 511 is stored as instructions for execution by the processors 501 to cause the computer system 500 to operate, such as is described herein below with respect to the various Figures. Examples of computer program product and the execution of such instruction is discussed herein in more detail. The communications adapter 507 interconnects the system bus 502 with a network 512, which can be an outside network, enabling the computer system 500 to communicate with other such systems. In one embodiment, a portion of the system memory 503 and the mass storage 510 collectively store an operating system, which can be any appropriate operating system to coordinate the functions of the various components shown in FIG. 5.

Additional input/output devices are shown as connected to the system bus 502 via a display adapter 515 and an interface adapter 516. In one embodiment, the adapters 506, 507, 515, and 516 can be connected to one or more I/O buses that are connected to the system bus 502 via an intermediate bus bridge (not shown). A display 519 (e.g., a screen or a display monitor) is connected to the system bus 502 by the display adapter 515, which can include a graphics controller to improve the performance of graphics intensive applications and a video controller. A keyboard 521, a mouse 522, a speaker 523, etc., can be interconnected to the system bus 502 via the interface adapter 516, which can include, for example, a Super I/O chip integrating multiple device adapters into a single integrated circuit. Suitable I/O buses for connecting peripheral devices such as hard disk controllers, network adapters, and graphics adapters typically include common protocols, such as the Peripheral Component Interconnect (PCI) and the Peripheral Component Interconnect Express (PCIe). Thus, as configured in FIG. 5, the computer system 500 includes processing capability in the form of the processors 501, storage capability including the system memory 503 and the mass storage 510, input means such as the keyboard 521 and the mouse 522, and output capability including the speaker 523 and the display 519.

In some embodiments, the communications adapter 507 can transmit data using any suitable interface or protocol, such as the internet small computer system interface, among others. The network 512 can be a cellular network, a radio network, a wide area network (WAN), a local area network (LAN), or the Internet, among others. An external computing device can connect to the computer system 500 through the network 512. In some examples, an external computing device can be an external webserver or a cloud computing node.

It is to be understood that the block diagram of FIG. 5 is not intended to indicate that the computer system 500 is to include all of the components shown in FIG. 5. Rather, the computer system 500 can include any appropriate fewer or additional components not illustrated in FIG. 5 (e.g., additional memory components, embedded controllers, modules, additional network interfaces, etc.). Further, the embodiments described herein with respect to computer system 500 can be implemented with any appropriate logic, wherein the logic, as referred to herein, can include any suitable hardware (e.g., a processor, an embedded controller, or an application specific integrated circuit, among others), software (e.g., an application, among others), firmware, or any suitable combination of hardware, software, and firmware, in various embodiments.

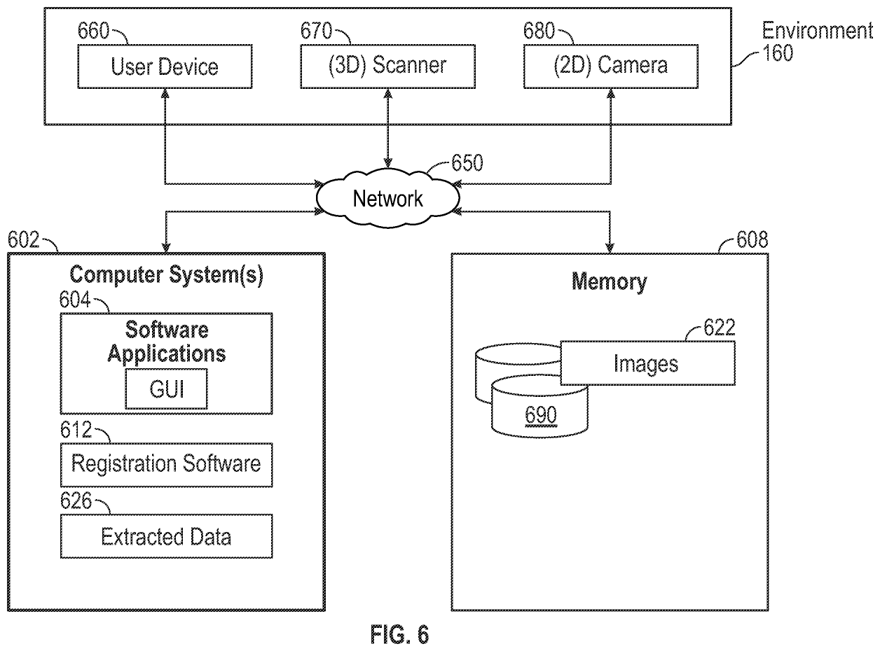

FIG. 6 is a block diagram of a computer system 602 for operating a BIM system from a web app using captured point clouds according to one or more embodiments. Elements of computer system 500 may be used in and/or integrated in computer system 602 and user device 660. An environment 160 may include a scanner 670 such as the laser scanner 20 discussed in FIGS. 1, 2, 3, and 4 and/or another suitable three-dimensional coordinate scanning device. The environment 160 may include a camera 680, for example, having features of the cameras 66, 112 of laser scanner 20 depicted in FIGS. 1-4 and/or another suitable camera. The scanner 670 is configured to measure three-dimensional coordinates of points in the environment or on an object. The scanner 670 may be a time-of-flight scanner, a triangulation scanner, an area scanner, a structured light scanner, or a laser tracker for example.

Data 690 in memory 608 can include 3D point clouds of the environment 160, also referred to as 3D point cloud data, point clouds, 3D images, etc. The 3D point cloud includes 3D point cloud data points. Data 690 in memory 608 may include 2D images of the environment 160. In an embodiment, the 2D images can include panorama images acquired while performing photogrammetry at a scene in the environment 160. The memory 608 can be part of a cloud platform or any other computer server on which the reality capture data (data 690) is stored, in some aspects. The data 690 can be accessed via the network 605. Alternatively, the memory can be part of the computer systems 602.

The computer systems 602 execute one or more software applications 604 (i.e., computer programs). The software applications 604 and/or parts/modules of the software applications 604 can be used with, integrated in, called, and/or be called by other software applications, e.g., operating systems, web-browsers, photogrammetry software, word processing software, spreadsheet software, BIM software, drawing software, or any other third-party applications or a combination thereof. The software applications 604 facilitate processing 3D point cloud data and 2D images as understood by one of ordinary skill in the art.

In one or more embodiments, software application 604 can be employed by a user for processing and manipulating 2D images and 3D point cloud data using a user interface such as, for example, a keyboard, mouse, touch screen, stylus, etc. Software application 604 can include and/or work with a graphical user interface (GUI). Features of the software application 604 can receive input commands and data to facilitate interplay between a first software application that facilitates interacting with the reality capture data (e.g., point clouds) and a second software application that is a BIM, as discussed herein. As understood by one of ordinary skill in the art, software application 604 includes functionality and/or is integrated with other software for processing any 2D image and 3D image including a 3D point cloud. In one or more embodiments, the software application 604 can include features of, be representative of, and/or be implemented in FARO® Zone 2D Software, FARO® Zone 3D Software, FARO® PhotoCore Software, FARO® Scene Software, or any other software program which are provided by FARO® Technologies, Inc., or any other third party vendor.

The various components, modules, engines, etc., described regarding the computer system 602, the user device 660, the scanner 670, and the camera 680 can be implemented as instructions stored on a computer-readable storage medium, as hardware modules, as special-purpose hardware (e.g., application specific hardware, application specific integrated circuits (ASICs), application specific special processors (ASSPs), field programmable gate arrays (FPGAs), as embedded controllers, hardwired circuitry, etc.), or as some combination or combinations of these. According to aspects of the present disclosure, the engine(s) described herein can be a combination of hardware and programming. The programming can be processor executable instructions stored on a tangible memory, and the hardware can include the computer system 602 for executing those instructions. Thus, a system memory (not shown) can store program instructions (e.g., software applications 604) that when executed by the computer system 602 implement the engines described herein. Other engines can also be utilized to include other features and functionality described in other examples herein.

A network adapter (not shown) provides for the computer system 602 to transmit data to and/or receive data from other sources, such as other processing systems, data repositories, and the like. As an example, the computer system 602 can transmit data to and/or receive data from the camera 680, the scanner 670, and/or the user device 660 directly and/or via a network 650.

The network 650 represents any one or a combination of different types of suitable communications networks such as, for example, cable networks, public networks (e.g., the Internet), private networks, wireless networks, cellular networks, or any other suitable private and/or public networks. Further, the network 650 can have any suitable communication range associated therewith and may include, for example, global networks (e.g., the Internet), metropolitan area networks (MANs), wide area networks (WANs), local area networks (LANs), or personal area networks (PANs). In addition, the network 650 can include any type of medium over which network traffic may be carried including, but not limited to, coaxial cable, twisted-pair wire, optical fiber, a hybrid fiber coaxial (HFC) medium, microwave terrestrial transceivers, radio frequency communication mediums, satellite communication mediums, or any combination thereof.

The camera 680 can be a 2D camera or a 3D camera (RGBD or time-of-flight for example). The camera 680 captures an image (or multiple images), such as of an environment 160. The camera 680 transmits the images to the computer system 602. In one or more embodiments, the camera 680 encrypts the image before transmitting it to the computer system 602. Although not shown, the camera 680 can include components such as a processing device, a memory, a network adapter, and the like, which may be functionally similar to those included in the computer system 500, 602 as described herein.

In some examples, the camera 680 is mounted to a mobile base, which can be moved about the environment 160. In some examples, the camera 680 is disposed in or mounted to an unmanned aerial vehicle. In various examples, the camera 680 is mounted on a manned aerial vehicle and/or unmanned aerial vehicle, generally referred to as a drone. In some examples, the camera 680 is mounted to a fixture, which is user-configurable to rotate about a roll axis, a pan axis, and a tilt axis. In such examples, the camera 680 is mounted to the fixture to rotate about the roll axis, the pan axis, and the tilt axis. Other configurations of mounting options for the camera 680 also are possible.

A coordinate measurement device, such as scanner 670 for example, is any suitable device for measuring 3D coordinates or points in an environment, such as the environment 160, to generate data about the environment. The scanner 670 may be implemented as a TOF laser scanner 20. A collection of 3D coordinate points is sometimes referred to as a point cloud. According to one or more embodiments described herein, the scanner 670 is a three-dimensional (3D) laser scanner time-of-flight (TOF) coordinate measurement device. It should be appreciated that while embodiments herein may refer to a laser scanner, this is for example purposes and the claims should not be so limited. In other embodiments, other types of coordinate measurement devices or combinations of coordinate measurement devices may be used, such as but not limited to triangulation scanners, structured light scanners, laser line probes, photogrammetry devices, and the like. A 3D TOF laser scanner steers a beam of light to a non-cooperative target such as a diffusely scattering surface of an object. A distance meter in the scanner 670 measures a distance to the object, and angular encoders measure the angles of rotation of two axles in the device. The measured distance and two angles enable a processor in the scanner 670 to determine the 3D coordinates of the target.

A TOF laser scanner, such as the scanner 670, is a scanner in which the distance to a target point is determined based on the speed of light in air between the scanner and a target point. Laser scanners are typically used for scanning closed or open spaces such as interior areas of buildings, industrial installations, and tunnels. They may be used, for example, in industrial applications and accident reconstruction applications. A laser scanner, such as the scanner 670, optically scans and measures objects in a volume around the scanner 670 through the acquisition of data points representing object surfaces within the volume. Such data points are obtained by transmitting a beam of light onto the objects and collecting the reflected or scattered light to determine the distance, two-angles (i.e., an azimuth and a zenith angle), and optionally a gray-scale value. This raw scan data is collected and stored as a point cloud, which can be transmitted to the computer system 602 and stored in the database 690 about the environment 160.

In some examples, the scanner 670 is mounted to a mobile base, which can be moved about the environment 160. In some examples, the scanner 670 is disposed in or mounted to an unmanned aerial vehicle. In various examples, the scanner 670 is mounted on a manned aerial vehicle and/or unmanned aerial vehicle, generally referred to as a drone. In some examples, the scanner 670 is mounted to a fixture, which is user-configurable to rotate about a roll axis, a pan axis, and a tilt axis. In such examples, the scanner 670 is mounted to the fixture to rotate about the roll axis, the pan axis, and the tilt axis. Other configurations of mounting options for the scanner 670 also are possible.

According to one or more embodiments described herein, the camera 680 captures 2D image(s) of the environment 160 and the scanner 670 captures 3D information of the environment 160. In some examples, the camera 680 and the scanner 670 are separate devices; however, in some examples, the camera 680 and the scanner 670 are integrated into a single device. For example, the camera 680 can include depth acquisition functionality and/or can be used in combination with a 3D acquisition depth camera, such as a time of flight camera, a stereo camera, a triangulation scanner, LIDAR, and the like. In some examples, 3D information can be measured/acquired/captured using a projected light pattern and a second camera (or the camera 680) using triangulation techniques for performing depth determinations. In some examples, a time-of-flight (TOF) approach can be used to enable intensity information (2D) and depth information (3D) to be acquired/captured. The camera 680 can be a stereo-camera to facilitate 3D acquisition. In some examples, a 2D image and 3D information (i.e., a 3D data set) can be captured/acquired at the same time; however, the 2D image and the 3D information can be obtained at different times.

The user device 660 (e.g., a smartphone, a laptop or desktop computer, a tablet computer, a wearable computing device, a smart display, and the like) can also be located within or proximate to the environment 160. In some aspects, the user device 660 is located outside the environment 160 and can access the data 690 in a remote offline manner. The user device 660 can display an image of the environment 160, such as on a display of the user device 660 (e.g., the display 519 of the computer system 500 of FIG. 5) along with a digital visual element. In some examples, the user device 660 can include components such as a processor, a memory, an input device (e.g., a touchscreen, a mouse, a microphone, etc.), an output device (e.g., a display, a speaker, etc.), and the like.

The registration software 612 facilitates registration of one or more captured reality data, e.g., point clouds, 2d scans, images, etc., with each other. The registration can be performed using one or more known or later developed techniques.

In one or more aspects, the software applications extract data (extracted data 626) from a selected point or a selected area/portion of the reality capture data (690). The extracted data 626 can be used to remote control the BIM. In some aspects, the extracted data 626 includes direct measurements, e.g., coordinates (i.e., points—3D or 2D), distances, angular measurements, etc. The extracted data can further include derived measurements, e.g., smart features like corners, edges or points derived from geometric primitives (e.g., center point of a detected sphere or points on the axis of a cylindrical objects). Alternatively, or in addition, the extracted data 626 includes complex BIM objects, such as architectural objects (walls, stairs, etc.), engineering objects (pipes, ducts, etc.), items or fixtures in the environment (furniture, fire-extinguishers, defibrillators, first-aid boxes, conveyors, assembly lines, etc.).

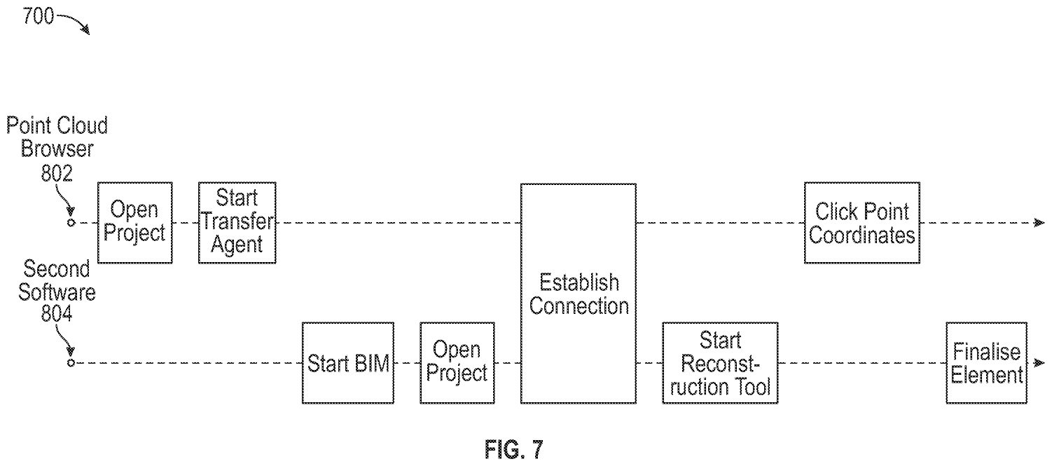

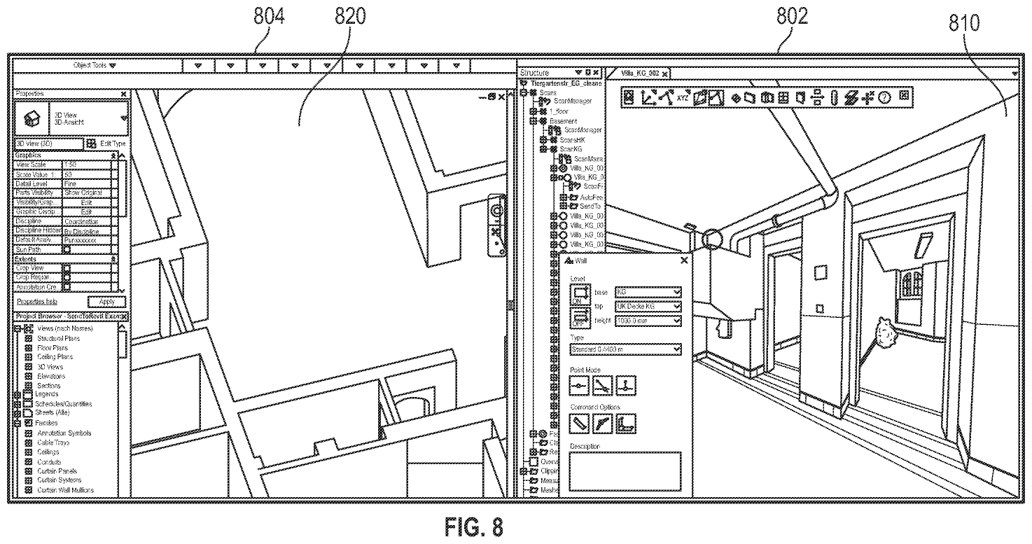

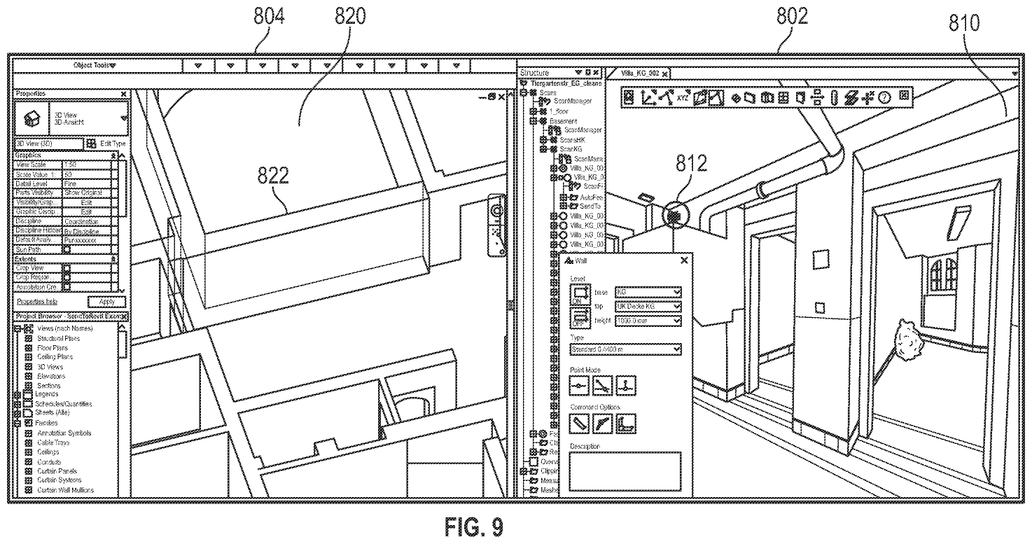

FIG. 7 depicts an operational flow of a method to remotely control a BIM using a web application according to one or more aspects. The depicted operational flow is described further in conjunction with an example scenario depicted in FIGS. 8-9. It should be noted that the example described herein uses a BIM 804 as an example second software (804) that is remotely controlled using a point cloud browser software (web app) 802. However, in one or more aspects, the second software can be any other type of software, such as a word processing software, a spreadsheet software, a drawing software, etc. Further, the point cloud browser software 802 can be a desktop (or non-web) application in one or more aspects.

FIG. 8 depicts an example with the point cloud browser 802 and the BIM 804 shown in a side-by-side view. It is understood that the two software applications may be positioned differently in other aspects. The point cloud browser 802 depicts a point cloud 810 that is being viewed. The point cloud 810 is that of an interior of a building, however, in other aspects, the point cloud 810 can represent any other environment 160. The point cloud 810 includes several architectural features, such as walls, doors, pipes, steps, beams, door frames, electrical connections, and other stationary objects in environment captured. Fewer or additional architectural (or other type of) features can exist in the point cloud 810 in other aspects.

The BIM 804 has a model 820 open. The model 820 represents a digital representation of an interior of a building. It should be noted that the model 820 may be being generated or edited in some aspects. The model 820 may be of the same environment 160 of which the point cloud 810 is captured. In other aspects, the model 820 may be of a different environment, and where the model 820 is (still) being generated or edited using the point cloud 810 as reference.

It should be noted that the depicted point cloud browser 802 and BIM 804 are examples, and that in other aspects any other point cloud browser and BIM can be used.

Referring to the FIG. 7, in one or more aspects, a new project may be started to link the point cloud 810 with the model 820. In some aspects, the new project may be started and then the point cloud 810 and/or the model 820 are selected. A connection is established between the point cloud browser 802 and the BIM 804. In one or more aspects, a transfer agent component is embedded in the point cloud browser app 802 and/or the BIM 804. For example, the transfer agent can be a plugin (or plugins).

The transfer agent (“agent”) has access to the native data model of the BIM 804, for example, via an application programming interface (API) that the BIM 804 provides. Accordingly, the transfer agent can translate data sent from the point cloud browser 802 into native BIM objects like walls, stairs, duct systems etc.

For example, once the connection between the point cloud browser 802 and the BIM 804 is established, an operator can remotely operate the BIM 804 via the point cloud browser 802. For example, the operator can select one or more points, or areas in the point cloud 810, and corresponding response is automatically performed in the BIM 804.

For example, referring to FIG. 9, the operator may select a wall in the point cloud 810 by clicking (or any other interaction) at point/area 812. In some aspects, the point cloud browser 802 identifies the object/feature that comprises the point at which the operator clicks. The identification may be performed using one or more techniques of computer vision. In response to the selection of the wall based on the point 812, the model 820 in the BIM 804 is populated with a wall 822. The wall 822 is added to a predetermined position in the model 820. In some aspects, the operator can identify the position using a selection interaction (e.g., clicking, etc.) before selecting the point 812. Alternatively, or in addition, the wall 822 can repositioned in the model 820 after it is added to the model 820.

The wall 822 is added to match one or more attributes of the selected wall in the point cloud 810. To achieve this, the transfer agent extracts data associated with the selected wall based on the selection of the point 812. For example, the extracted data can include 3D points, distance, or angular measurements. Alternatively, or in addition, the extracted data can also include derived data, such as smart features like corners, edges or points derived from geometric primitives (e.g., center point of a detected sphere or points on the axis of a cylindrical objects). Alternatively, or in addition, the extracted data can also include identified objects, such as architectural objects (walls, stairs, . . . ), engineering objects (pipes, ducts, . . . ), etc.

In some aspects, the agent causes the extracted data to be identified on the cloud, i.e., the computer server where the point cloud data is stored so as to avoid resource intensive downloads and analysis of the point cloud. Accordingly, only a minimal amount of data has to be transferred over the network, which includes the extracted data. In this manner, technical solutions facilitate improving efficiency of the BIM workflow.

The transfer agent inputs the extracted data into the BIM 804 via the API and creates corresponding data in the model 820. The transfer agent, in some aspects, uses the extracted data to send commands into the BOM 804 to create the corresponding objects, such as the wall 822, in the model 820. In some aspects, the commands can be generated as machine-executable instructions that are to be executed by the BIM 804. The commands can be input either as API calls, or via a command-line prompt of the BIM 804. In other aspects, the transfer agent creates one or more macros, scripts, or other types of computer program that are executed by the BIM 804.

In other aspects, the agent component translates data from the point cloud browser 802 into a sequence of commands and measurements suitable as input to the BIM 804. This command sequence is sent to the connected target application window as emulated keyboard input (or any other type of input accepted by the BIM 804 or target application). Because the output of the transfer agent emulates any other input, the transfer agent may not be limited to particular target application, rather any application which is able to process keyboard input can be targeted by the transfer agent application.

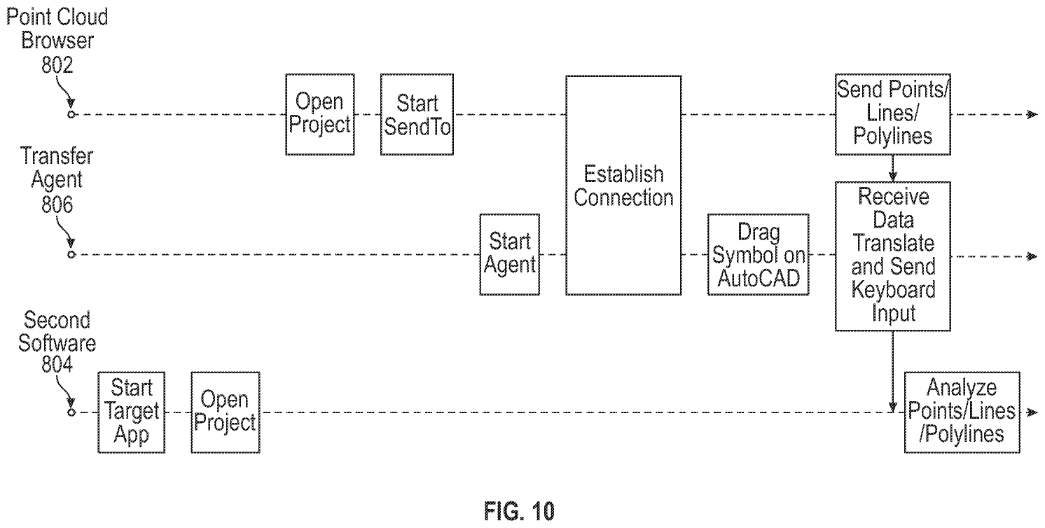

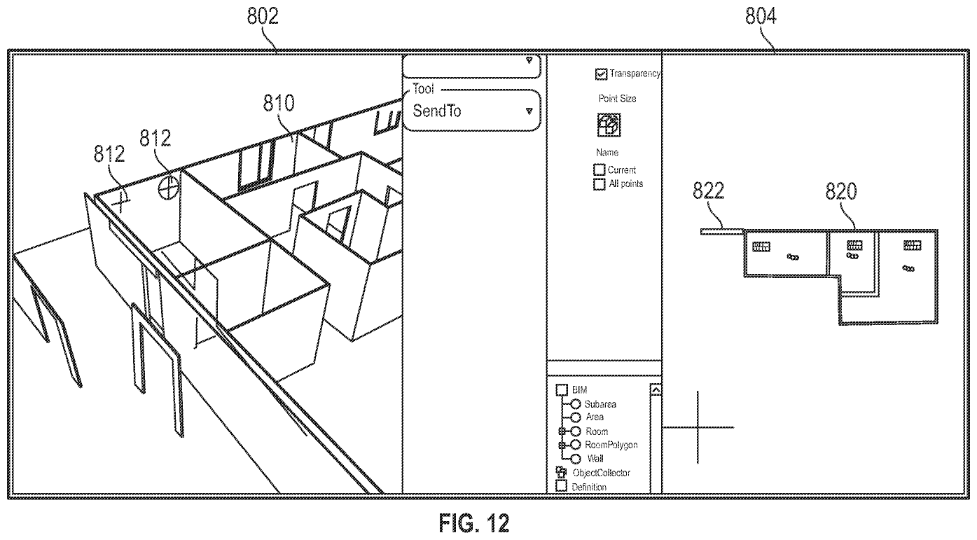

FIG. 12 depicts another example of remotely operating a target application, e.g., BIM 804 via selection of one or more points in the point cloud 810 in the point cloud browser 802. Here, the selection 812 can include selecting two points in the point cloud 810, as shown. The selection 812 can be performed by drawing a line between the two selected points. It should be noted that in other aspects the selection 812 can include any other type of shape, square, rectangle, circle, etc. Corresponding to the selection 812, a wall 822 is added in the model 820 in the BIM 804. In this case the model is depicted as a 2D plan (instead of a 3D model in FIG. 10).

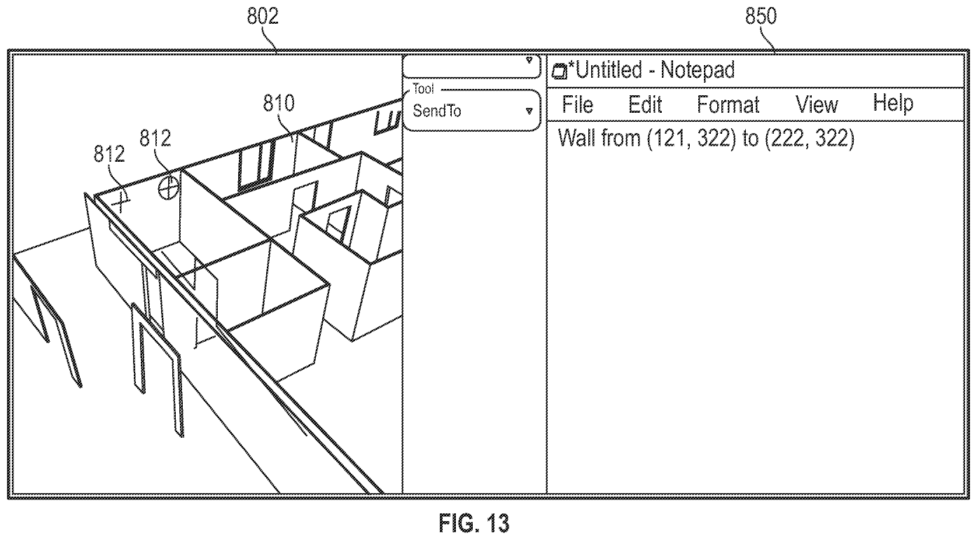

FIG. 13 depicts another example of remotely operating a target application, e.g., word processing application 850 via selection of one or more points in the point cloud 810 in the point cloud browser 802. Here, the selection 812 can include selecting two points in the point cloud 810, as shown. The selection 812 can be performed by drawing a line between the two selected points. It should be noted that in other aspects the selection 812 can include any other type of shape, square, rectangle, circle, etc. Corresponding to the selection 812, the extracted data is added in the document, or digital file of the application 805. The extracted data can be added either by performing a keyboard emulation using the extracted data. Alternatively, or in addition, the extracted data is added by using one or more APIs of the application 850.

FIG. 10 depicts the operational workflow of operating the BIM 804 remotely via the point cloud browser 802 according to one or more aspects. Here, the transfer agent 806 is shown as a standalone application (instead of being embedded in the point cloud browser 802 and/or BIM 804 in FIG. 7). For example, the agent 806 is a standalone application (software/computer program), which can be connected to the point cloud browser 802 and the BIM 804. It is understood that although BIM 804 is used as the example herein, the software 804 can be any target application.

In some aspects, to establish a connection between the point cloud browser 802 and the target application, window of the two applications to be connected (802, 804) are identified to the transfer agent 806. For example, the windows, and in turn, the applications 802, 804 are identified to the transfer agent 806 by using a drag-and-drop-operation, i.e., the respective windows of the point cloud browser 802 and the BIM 804 are dragged and dropped into the transfer agent 806 window.

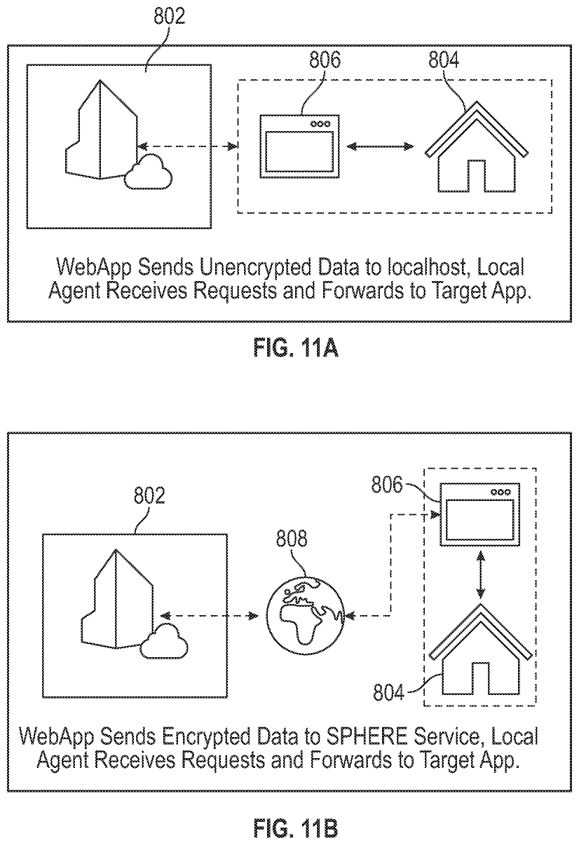

The communication between the point cloud browser 802 and the agent 806 component (regardless of whether it is embedded or as a standalone application) can be realized using several approaches. For example, as shown in FIG. 11A, a local server may be established on the computer system 602 to transfer data from the point cloud browser 802 to the transfer agent 806. For example, the agent 806 hosts a local server component (e.g., WebSocket™ server). The point cloud browser 802 directly connects to the local server when the transfer agent 806 is instantiated. The point cloud browser 802 further sends messages according to one or more specific protocols to the local server. The transfer agent 806 transfers data to the BIM 804 (or target application) using emulated keyboard input or API of the BIM 804. The data transferred by the point cloud browser 802 to the local server may or may not be secured, e.g., using encryption.

In other aspects, as shown in FIG. 11B, a message broker service is used to perform an indirect communication between the point cloud browser 802 and the agent 806. For example, a dedicated message broker cloud service 808 is used. For the communication to be performed, the agent 806 connects to the message broker service 808 (with a userID, an ApplicationID to receive incoming data. It is understood that other parameters may be used in other aspects. The point cloud browser 802 also connects to message broker service 808 with the same userID. The point cloud browser 802 requests the message broker service 808 for available ApplicationlDs presently connected with that userID. The message broker service sends back a list of ApplicationIDs, which includes the transfer agent 804. The point cloud browser 802 subsequently starts sending the extracted data with specified userID, ApplicationID to the message broker service 808. The message broker service 808 accordingly receives the extracted data, which is then forwarded directly to the addressed agent 806. It should be noted that such bidirectional communication does not use any extra storage for messages.

Technical solutions described herein facilitate remotely operating a target application, e.g., BIM, via a web-app, e.g., point cloud browser. The technical solutions are rooted in computing technology, particularly, interplay between two or more specific applications. Further, the technical solutions are rooted in computing technology, particularly in BIM to use captured digital representations of an environment in generating one or more digital models, such as in BIM.

Further, technical solutions herein provide practical applications. For example, architects and engineering service providers desire to plan new buildings or reshaping of existing buildings digitally first before the construction is executed (Building Information Modeling—BIM). In brownfield projects (as-built projects) there is the demand to capture the environment accurately and use this data for virtual design. This demand can be covered by point cloud data. But point clouds are huge. In terms of file size as well as performance consumption. Also, some design systems cannot import point cloud data at all. In order to save the architects/engineers time to get the as-built data from cloud ecosystem into their productive design systems technical solutions herein transfer the relevant data to create as-built model without having the point cloud data to be downloaded and imported and to accelerate the overall process to extract the relevant information from point cloud data to make it usable in the BIM workflow.

It will be appreciated that aspects described herein may be embodied as a system, method, or computer program product and may take the form of a hardware embodiment, a software embodiment (including firmware, resident software, micro-code, etc.), or a combination thereof. Furthermore, aspects of the embodiments described herein may take the form of a computer program product embodied in one or more computer readable medium(s) having computer readable program code embodied thereon.

One or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In one aspect, the computer readable storage medium may be a tangible medium containing or storing a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof, A computer readable signal medium may be any computer readable medium that is not a computer readable storage medium and that can communicate, propagate, or transport a program for use by or in connection with an instruction execution system, apparatus, or device.

The computer readable medium may contain program code embodied thereon, which may be transmitted using any appropriate medium, including but not limited to wireless, wireline, optical fiber cable, RF, etc., or any suitable combination of the foregoing. In addition, computer program code for carrying out operations for implementing aspects of the embodiments described herein may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server.

It will be appreciated that embodiments described herein are described herein with reference to flowchart illustrations and/or block diagrams of methods, apparatus (systems) and computer program products according to embodiments described herein. It will be understood that each block or step of the flowchart illustrations and/or block diagrams, and combinations of blocks or steps in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks. The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

Terms such as processor, controller, computer, DSP, FPGA are understood in this document to mean a computing device that may be located within an instrument, distributed in multiple elements throughout an instrument, or placed external to an instrument.

While embodiments of the invention have been described in detail in connection with only a limited number of embodiments, it should be readily understood that embodiments of the invention are not limited to such disclosed embodiments. Rather, embodiments of the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, embodiments of the invention are not to be seen as limited by the foregoing description, but is only limited by the scope of the appended claims.

What is claimed is:

1. A computer-implemented method comprising:
establishing a connection between a point cloud browser and a transfer agent;
establishing a connection between the transfer agent and a target application; and
in response to selection of one or more points in the point cloud browser, generating one or more objects in the target application.

2. The computer-implemented method of claim 1, wherein the one or more objects comprise at least one of a graphical element, a textual element, and a computer-executable instruction.

3. The computer-implemented method of claim 1, wherein the point cloud browser displays a point cloud stored on a remote computer server, and in response to the selection of the one or more points, an extracted data is generated corresponding to the selection.

4. The computer-implemented method of claim 3, wherein only the extracted data is sent for receipt by the transfer agent.

5. The computer-implemented method of claim 4, wherein the transfer agent generates the one or more objects in the target application by generating one or more commands that use the extracted data, the commands based on an application programming interface of the target application.

6. The computer-implemented method of claim 4, wherein the transfer agent generates the one or more objects in the target application by emulating a keyboard input that is provided to the target application.

7. A system comprising:
a memory comprising computer readable instructions; and
a processing device for executing the computer readable instructions, the computer readable instructions controlling the processing device to perform operations comprising:
establishing a connection between a point cloud browser and a transfer agent;
establishing a connection between the transfer agent and a target application; and
in response to selection of one or more points in the point cloud browser, generating one or more objects in the target application.

8. The system of claim 7, wherein the one or more objects comprise at least one of a graphical element, a textual element, and a computer-executable instruction.

9. The system of claim 7, wherein the point cloud browser displays a point cloud stored on a remote computer server, and in response to the selection of the one or more points, an extracted data is generated corresponding to the selection.

10. The system of claim 9, wherein only the extracted data is sent for receipt by the transfer agent.

11. The system of claim 10, wherein the transfer agent generates the one or more objects in the target application by generating one or more commands that use the extracted data, the commands based on an application programming interface of the target application.

12. The system of claim 10, wherein the transfer agent generates the one or more objects in the target application by emulating a keyboard input that is provided to the target application.

13. A computer program product comprising a computer readable storage medium having program instructions embodied therewith, the program instructions executable by one or more processors to cause the one or more processors to perform operations comprising:
establishing a connection between a point cloud browser and a transfer agent;
establishing a connection between the transfer agent and a target application; and
in response to selection of one or more points in the point cloud browser, generating one or more objects in the target application.

14. The computer program product of claim 13, wherein the one or more objects comprise at least one of a graphical element, a textual element, and a computer-executable instruction.

15. The computer program product of claim 13, wherein the point cloud browser displays a point cloud stored on a remote computer server, and in response to the selection of the one or more points, an extracted data is generated corresponding to the selection.

16. The computer program product of claim 15, wherein only the extracted data is sent for receipt by the transfer agent.

17. The computer program product of claim 16, wherein the transfer agent generates the one or more objects in the target application by generating one or more commands that use the extracted data, the commands based on an application programming interface of the target application.

18. The computer program product of claim 16, wherein the transfer agent generates the one or more objects in the target application by emulating a keyboard input that is provided to the target application.
